(19) United States
(12) Patent Application Publication
(10) Pub. No.: US 2026/0235703 A1
(43) Pub. Date: Aug. 13, 2026

(54) METHOD FOR CHECKING A CABLE MATING OF A MULTI-BAND ANTENNA

(71) Applicant: Telefonaktiebolaget LM Ericsson (publ), Stockholm (SE)

(72) Inventors: Manfred STOLLE, Bad Aibling (DE); Christoph SPRANGER, Dorfen (DE)

(73) Assignee: Telefonaktiebolaget LM Ericsson (publ), Stockholm (SE)

(21) Appl. No.: 19/156,505

(22) PCT Filed: Feb. 24, 2023
(86) PCT No.: PCT/EP2023/054679

§ 371 Date: Aug. 14, 2025

(51) Int. Cl. G01R 31/67

(52) U.S. Cl. CPC G01R 31/67

(57) ABSTRACT

The present invention relates to a method (1000) for checking a cable mating between a radio unit (20, 22, 24) and a multi-band antenna (10, 14). The method comprises: monitoring (1100) a voltage standing wave ratio, VSWR, of the radio unit; IC changing (1200) a phase shift of a phase shifter Φ1, . . . Φ8 being assigned to an antenna port R11A, . . . Y62A of the multi-band antenna 10; determining (1300) a port R11R, . . . Y62R of the radio unit 20, where a change in the VSWR of the radio unit occurred due to the changing of the phase shift; checking (1400), whether the determined port R11R, . . . Y62R of the radio unit 20 corresponds to the antenna port R11A, . . . Y62A of the multi-band antenna 10, where the phase shift was changed, and outputting (1500, 1600) the result of the checking.

### TECHNICAL FIELD

The present invention relates to a method, particularly a computer implemented method, for checking a cable mating between a radio unit and a multi-band antenna. Further, the present invention relates to a computer program for checking said cable mating, to a phase shifter, to an analyzing device for checking said cable mating, to a radio unit and to a base station having implemented said method.

### BACKGROUND

Nowadays, mobile communication has become a crucial part of our daily lives. To implement mobile communication services for users and mobile devices, base stations play an essential role to constitute a complete network system by transmitting signals.

A base station (or radio base station) is a transceiver connecting a number of other devices to one another and/or to a wider area. In mobile communications, a base station provides the connection between user terminals (e.g. mobile phones, tablet computers, and the like) and/or other IoT devices (such as cars, drones, industrial and agricultural machines, robots, home appliances, medical devices, and the like) and/or the wider cellular network.

A base station may include the following components: (i) at least one base station antenna, (ii) a radio unit, (iii) a base band unit and (iv) a physical support. Further, there may be a remote control unit, allowing the antenna to be controlled remotely, e.g. for adjusting phase shifter(s) of the antenna, to provide for additional functionality, such as remote electrical tilt (RET).

The base station antenna(s) may be a passive antenna, particularly a passive multi-band antenna, which covers multiple frequency bands. Base station antennas used for wireless communication base stations are typically composed of multiple radiators (antenna elements) so as to enable radio frequency cellular communication with an improved transmission range and/or with distinct frequency bands. Such radiators may be formed as dual polarized radiators, such as dual polarized dipole radiators. Each of the antenna elements has to be electrically connected to at least one port of a radio unit for receiving/transmitting Rx/Tx signals. In case of a dual polarized radiator, said radiator is typically electrically connected to two respective ports of a radio unit for receiving/transmitting Rx/Tx signals.

The radio unit (also denoted as RRU, Remote Radio Unit, or RRH, Remote Radio Head) can be divided into several sub-units for the transmission of e.g. 2G, 3G, 4G and/or 5G signals. Further wireless communication standards may also be implemented. The signal generation and extraction of radio signals are typically performed here. Those radio units have become one of the most important components of today's (distributed) base stations. The radio unit typically contains the base station's RF circuitry, analog-to-digital/digital-to-analog converters and up/down converters. Typical radio units also have operation and management processing capabilities and a standardized optical interface to connect to the rest of the base station.

For connecting the radio unit to the antenna (antenna elements, respectively) typically jumper cables including radial-contact connectors are used (e.g. coaxial RF connectors). Connector systems, such as 4.3-10, 2.2-5, 1.5-3.5, the NEX10® connector system and/or the like are common. These connectors allow electrically connecting the radio unit with the antenna, particularly if the connector system is mounted directly floating. State of the art are RF-jumper cables between antenna (respectively antenna elements) and radio unit (respectively ports thereof) on the mast. A standard setup would e.g. by a radio unit being fixed below the antenna on the mast via ½ inch, ¼ inch or ⅜ inch RF-jumper cables.

The base band unit (BBU) is typically located remote from the radio unit (e.g. in a separate equipment room) and may be connected with the radio unit via an optical fiber, a dedicated high bandwidth wire or other suitable connections. The BBU processes an original signal.

The physical support mainly includes an electrical power system, which may include a backup battery (to prevent power failure), a transmission equipment, and further optionally an air conditioning system to maintain the optimal temperature for regular operation.

A typical mobile communication base station has e.g. three sectors. For each sector there is a multiband antenna, for example with a 2-column low band (R1, R2) and a 4-column mid band (Y1, Y2, Y3, Y4). Each column includes a dual polarized radiator, e.g. a dual polarized dipole, including two connectors. Therefore, a respective multi-band antenna for said sector would have 12 connectors.

Accordingly, a three-sector base station would have 36 connectors (3×12) These 36 connectors have to be wired by 36 jumper cables with respective 36 counter connectors of a radio unit or multiple (at least two) radio units.

It is to be understood, that a base station may include different sectors and/or bands. For example, the following bands and/or others may be part of a base station:

| | |
|---|---|
| R1: | 698-960 MHz |
| R2: | 698-960 MHz |
| Y1: | 1695-2700 MHz |
| Y2: | 1695-2700 MHz |
| Y3: | 1695-2700 MHz |
| Y4: | 1695-2700 MHz |
| Y5: | 1695-2700 MHz |
| Y6: | 1695-2700 MHz |
| P1: | 3400-4200 MHz |
| P2: | 3400-4200 MHz |
| P3: | 3400-4200 MHz |
| P4: | 3400-4200 MHz |

During the installation process of the base station (particularly during installation of the multiband antenna(s) and respective radio unit(s)), there is a risk of incorrect wiring, as connectors (ports) of the antenna(s) and counter connectors (ports) of the radio unit(s) may be interchanged or wrongly connected. For example, the Y1-port of a radio unit may be erroneously connected with a Y3-port of the antenna (same sector), or the Y1-port of a radio unit of a first sector may be erroneously connected with a Y1-port of an antenna of a second, different sector.

In case the ports are interchanged, the base station does not work properly so the available radiated power is reduced and additional functions, such as phase shifting, are disturbed. Further, the radio unit and/or antenna element may even get damaged due to an incorrect wiring.

Incorrect wiring is in particular an issue, as each base station and/or base station antenna is configured individually. Hence, assembling and setting up a base station/base station antenna implies a huge workload for the workers, including correct mating and connecting every single cable between the antenna and respective radio unit(s). Despite the highest care, there is always a risk of incorrect connections.

To detect incorrect wiring, in the art port pinging is used. Port pinging requires that the radio unit(s) is/are equipped with additional hardware and software that allows sending a respective pinging signal. Further, the antenna needs to be provided with means for receiving said pinging signal or vice versa.

In other words, for each connector (port) of the multi-band antenna which should be able to receive the pinging signal, there has to be implemented e.g. a bias tee. In practice, to reduce complexity and costs, only one port of a dual polarized radiator is provided with the possibility to receive the pinging signal. In the example given above, the 12-port multi-band antenna would need six bias tees. While still being expensive, an incorrect wiring of the ports that are not suited to receive the pinging signal cannot be detected.

Further, EP 3 136 628 A1 suggests an antenna line device installed in each antenna apparatus of a multiple antenna system, including a control part for controlling according to control signal from a base station body, and at least two of a DC ping part, RF ping part and domain detection part.

### SUMMARY

In view of the above, an object of the present invention is to improve the detection of mistakes in the cable mating and/or to confirm a correct cable mating.

The object is achieved by a method, particularly a computer implemented method for checking a cable mating between a radio unit and a multi-band antenna. Further, the present invention relates to a computer program for checking said cable mating, to a phase shifter, to an analyzing device, to a radio unit for checking said cable mating and to a base station having implemented said method. Further aspects are given in the dependent claims.

Particularly, the object is achieved by a method for checking a cable mating between a radio unit and a multi-band antenna.

The multi-band antenna may include different bands, including (but not limited to) at least some of the following: R1, R2, Y1, Y2, Y3, Y4, Y5, Y6, P1, P2, P3 and/or P4. Each of the bands (or at least some of them) may include a dual polarized radiator, e.g. a dual polarized dipole.

The radio unit may be a Remote Radio Unit, RRU or a Remote Radio Head, RRH and may be configured for the transmission of 2G, 3G, 4G and/or 5G signals. Further wireless communication standards may also be implemented. The ports of the radio unit (or at least some of them) are mated with antenna ports of the multi-band antenna. The inventive method allows checking the mating, i.e. detecting incorrect mating (such as interchanged ports) and/or confirming a correct cable mating. For performing the method no specific hardware, such as bias tees needed for port pinging, is required. Thus, the method may be entirely implemented in software. In other words, the method may be a computer-implemented method. This method may be performed on a control unit of a base station (e.g. a BBU), on a radio unit and/or on an analyzing device.

The method comprises:
monitoring a voltage standing wave ratio, VSWR, of the radio unit;
changing a phase shift of a phase shifter being assigned to an antenna port of the multi-band antenna;
determining a port of the radio unit, where a change in the VSWR of the radio unit occurred due to the changing of the phase shift, and checking, whether the determined port of the radio unit corresponds to the antenna port of the multi-band antenna, where the phase shift was changed, and
additionally, and/or alternatively to the previous step, checking whether a change in the VSWR of the radio unit occurred at an intended port, the intended port being assigned to the antenna port where the phase shift change was applied, and
outputting the result of the checking.

The method may be repeated, until the phase-shift of all antenna ports was changed, i.e. until the entire mating of the multi-band antenna is checked.

The step of monitoring a voltage standing wave ratio, VSWR, of the radio unit may include receiving a VSWR monitoring signal, e.g. by a control unit of a base station (e.g. a BBU), by the radio unit and/or on an analyzing device.

The VSWR (Voltage standing wave ratio) is the ratio between the transmitted power of the radio and the reflected power to the radio at a respective port of the radio unit. It is to be understood, that monitoring the VSWR may also include monitoring physical quantities that can be calculated from the VSWR, such as PSWR (power standing wave ratio) and/or physical quantities that serve for calculating the VSWR. The VSWR (as the PSWR) is dependent on the phase shift applied on the antenna port of the multiband antenna the port of the radio unit is connected to. Particularly, the VSWR will significantly change, if e.g. the phase shift of a phase shifter being assigned to an antenna port of the multi-band antenna is changed from a minimum value to a maximum value and/or vice versa. Thus, the step of changing a phase shift may include changing the phase shift from a minimum value to a maximum value and/or vice versa.

The change of the VSWR due to the changed/changing phase shift may be monitored. If correctly mated, the antenna port, where the phase shift change was applied on matches the intended port of the radio unit. I.e. the VSWR change is determined during monitoring at the intended port of the radio unit. Accordingly, the mating of the respective antenna port is OK.

In case the mating is incorrect (e.g. as ports are interchanged due to incorrect mating of jumper cables) the antenna port, where the phase shift change was applied on does not match the intended port of the radio unit. I.e. the VSWR change is determined during monitoring at a port being different than the intended port of the radio unit and/or there is no significant VSWR change determined at the intended port of the radio unit. Accordingly, the mating of the respective antenna port is NOK.

Hence, by determining the port of the radio unit, where a change in the VSWR of the radio unit occurred due to the changing of the phase shift allows to check, whether the determined port of the radio unit corresponds to the antenna port of the multi-band antenna, where the phase shift was changed.

This checking result may then be outputted, e.g. on a graphical user interface. Further, the checking result may be outputted to a further entity of the base station, and/or the like. Thus, during and/or after installation of the jumper cables, the correct mating may immediately be confirmed and/or mating errors may be detected.

Further, the step of changing a phase shift of a phase shifter may include commanding a phase shift changing element (e.g. a wiper or a slider) of a phase shifter to move beyond a position corresponding to a minimum phase shift value or a maximum phase shift value so as to electrically couple with a ground coupling element of the phase shifter. As will be described in greater detail below, this allows to check the cable mating of radiators being differently polarized.

Further, the method may include a step of determining and/or outputting, which of the ports of the radio unit and antenna ports are interchanged. This step may be repeated for each of the antenna ports (and ports of the radio unit, respectively), or a list and/or a map of interchanged ports may be generated and outputted. This list/map may show the actual mating of the ports (antenna ports and ports of the radio unit). Based on the list/map, the mating can easily be changed and therefore corrected.

The method may further comprise a step of determining, whether all ports whose mating is to be checked are correctly mated. These may be all ports of the multi-band antenna and/or assigned radio unit(s). Optionally, mobile communication via the multi-band antenna may be enabled only after having proved that all ports whose mating is to be checked are correctly mated. Thus, damages due to incorrect mating can be effectively prevented.

Further, the step of changing a phase shift may include sending a phase shift changing command to a remote electrical tilt, RET, unit of the multi-band antenna. This phase shift changing command may instruct the RET to change a phase shift of a phase shifter being assigned to an antenna port of the multi-band antenna. Hence, the method can be performed remotely.

In a particular aspect, the phase shift changing command and/or the VSWR monitoring signal may be transmitted via AISG signaling or other communication lines.

For communication between single components of a base station (e.g. the base station antenna, at least one radio unit and/or at least one base band unit) known standards may be used, and may be adapted to allow carrying out the above method. Particularly, the communication between the multi-band antenna (base station antenna) and the other components of the base station, such as the at least one radio unit and/or at least one base band unit may include transmitting of VSWR monitoring signals and/or phase shift changing commands.

For example, the AISG standard of the Antenna Interface Standards Group (AISG) may be utilized for carrying out the inventive method. The AISG-Group creates and maintains standards for a control and monitoring interfaces of base station components, particularly including antennas with remote electrical tilt (RET) and tower mounted amplifiers or RRUs. The latest version of the AISG standard (v3.0.4.4, released on Jan. 31, 2022) provides for base station components with multiple control ports that may each be connected to different controllers (e.g. BBUs), as well as the ability for the controller to map the RF system interconnections between components connected via a bus.

Further, the Common Public Radio Interface (CPRI) standard defines the interface of base stations between the Radio Equipment Controllers (REC, e.g. BBUs, CUs, or DUs) in the standard, to local or remote radio units, known as Radio Equipment (RE), such as a RRU. Traditionally, CPRI links are over an optical fiber, which can be as short distance CPRI link (i.e. up/down a tower/building, e.g. from Baseband Unit in a cabinet typically located at the base of the tower, to radio units at the top of tower/building), or a longer distance CPRI link (The BBU's are located centrally in a so called “Base Station Hotel” location e.g. in a city, connected across the city using longer fiber links to radio units at the top of each tower/building).

The CPRI standard is planned to evolve to eCPRI which runs over IP/Ethernet (eCPRI Specification V2.0 (2019 May 10)). The new specification will enhance the support for the 5G Front-haul by providing functionality to support CPRI (7.0) over Ethernet allowing for CPRI and eCPRI interworking. Further, the CPRI or eCPRI standard could be modified to allow for performing the above method.

Still further, the Open Base Station Architecture Initiative (OBSAI) may be used. OBSAI is a standard for the design and development of base station components used in wireless communication networks, such as those used in cellular and mobile networks. The OBSAI standard was developed to create a common interface between different vendors' base station components, allowing for more flexible network design and deployment.

Particularly, the OBSAI standard includes a set of specifications that define the functional and electrical interfaces between different base station components and may be adapted to include the above method.

According to a particular aspect, the communication between the radio unit and the multi-band antenna may be done via AISG signaling. Further, the multi-band antenna may be adapted for RET (remote electrical tilt).

The two phase shifters of a dual polarized antenna element will then e.g. be moved synchronic. Via the AISG signaling it can then be selected, at which antenna element (or band) the phase shifter should be moved (e.g. R1, R2, Y1, Y2, Y3, Y4, . . . ). Further, the multi-band antenna may include an unique identifier, such as a serial number. Thus, in case of a base station including multiple antennas (or sectors), phase shifters of an antenna element of a particular antenna can be controlled. Accordingly, the phase shift changing command may include a band-ID and/or an antenna element ID and/or an antenna ID.

Further, a transmission power of the radio unit and/or a transmission power of the port of the radio unit, where a change in the VSWR of the radio unit occurred due to the changing of the phase shift may be reduced or even shut off, if the VSWR exceeds a predefined VSWR-threshold. Typically, the VSWR-threshold is set to be 1.5, or to be 1.4 or to be 1.2 over the entire phase-shift range and for each frequency in the specified band.

In case the VSWR exceeds the threshold, i.e. in case the reflected power is too high, transmission power of the radio unit (or of the respective port) may be reduced until the threshold is met again and/or shut off. Further, an alarm may be set. So for example, the implemented VSWR alarm in the radio unit may detect a significant change in the reflected power or a significant change in the VSWR and may be used for checking the mating. Further, by reducing or shutting off the transmission power, damaging the radio unit and/or the multi-band antenna due to a high load of reflected power can be prevented.

Further, the method may comprise a step of correcting the mating of interchanged ports based on the outputted result of the checking (e.g. a generated list or map of the actual mating). This may be done manually, e.g. by re-mating respective jumper cables. Subsequently, the method may be repeated, until a correct mating is confirmed for all ports.

The object is further achieved by a computer program comprising instructions, which when executed by a processor cause the processor to perform a method as outlined above.

In a particular aspect, the object is achieved by a computer readable medium having stored thereon instructions, which when executed by a processor cause the processor to perform a method as outlined above.

The object is also achieved by a phase shifter that is adapted to be used in the method described above. Said phase shifter may be coupled with an antenna port of a multi-band antenna. Further the phase shifter comprises a phase shift changing element and a ground coupling element.

The phase shift changing element is arranged moveable from a first position (corresponding to a minimum phase shift value) to a second position (corresponding to a maximum phase shift value), wherein an area between the first position and the second position defines a phase shift changing area. The phase shift changing element may be rotatable (e.g. a wiper) or may be movable translationally (e.g. a slider).

Particularly, the phase shift changing element is moveable within this phase shift changing area to change a phase shift of the phase shifter.

The ground coupling element is electrically connected to ground and is arranged outside the phase shift changing area. The phase shift changing element is configured to be moved out of the phase shift changing area to electrically contact the ground coupling element.

In a particular aspect, the phase shifter is a first phase shifter that is assigned to a radiator of dual polarized antenna system (or antenna element) having a first polarization. A second phase shifter may be assigned to a further radiator of the dual polarized antenna system (or antenna element) having a second polarization, wherein the second phase shifter may have no such ground coupling element.

In case these first and second phase shifters, or respective phase shift changing elements thereof, are moved to change a phase shift, it is possible to check the cable mating of the differently polarized radiators.

As outlined above, a phase shift changing element of the first phase shifter may be moved beyond a position corresponding to a minimum phase shift value or a maximum phase shift value (i.e. out of the phase shift changing area) to electrically contact the ground coupling element.

If the phase shift changing element contacts the ground coupling element, the VSWR of the phase shifter will considerably increase. This increase of VSWR can be detected and it can be checked, whether the port of the radio, where the increase of the VSWR was detected corresponds to the indented radiator. If no change of VSWR is detected it can be concluded that second phase shifter was operated and that the mating is erroneous. Hence, the cable mating of the differently polarized radiators can be checked.

The movement of the phase shift changing element within the phase shift changing area and out of the phase shift changing area can e.g. be commanded via an AISG signal or any other suitable signaling.

Further, the object is achieved by an analyzing device. The analyzing device may include a processor and a memory. The memory may have stored instructions thereon, which when executed by the processor cause the processor to perform a method as outlined above. Further, the instructions may be loaded by the analyzing device from an external source, e.g. a cloud storage.

In a particular aspect, the analyzing device is adapted to communicate with at least one radio unit and at least one multi-band antenna, wherein the analyzing device adapted to perform the above method.

Further, the analyzing device may be adapted to communicate with a remote control unit assigned to said multi-band antenna. The communication may be wireless and/or wired. For example, AISG signaling may be used.

Further, the analyzing device may be a portable device and particularly a hand-held device (e.g. a portable computer, a smart phone or a tablet). Thus, a worker installing a radio unit and/or a multi-band antenna may perform the method using the portable analyzing device directly at the site and may identify and correct incorrect wiring immediately.

Further, the object is achieved by a radio unit, being adapted to communicate with a multi-band antenna and/or a remote control unit being assigned to said multi-band antenna, wherein the radio unit is further adapted to perform the above described method. The radio unit may include a processor and a memory. The memory may have stored instructions thereon, which when executed by the processor cause the processor to perform a method as outlined above. Further, the instructions may be loaded by the radio unit from an external source, e.g. a cloud storage.

The object is further achieved by a base station for mobile communication, the base station including at least one multi-band antenna and at least one radio unit being assigned to said multi-band antenna. The base station further including a control unit, wherein the control unit is adapted to communicate with the at least one radio unit and the at least one multi-band antenna. Particularly the control unit may be adapted to communicate with a remote control unit assigned to said multi-band antenna. For example, AISG signaling may be used for communication. The control unit is adapted to perform the above method.

E.g. the control unit may include a processor and a memory. The memory may have stored instructions thereon, which when executed by the processor cause the processor to perform a method as outlined above. Further, the instructions may be loaded by the radio unit from an external source, e.g. a cloud storage.

### BRIEF DESCRIPTION OF THE DRAWINGS

Further features and advantages will be apparent from the following description as well as the accompanying figures, to which reference is made. The figures show in detail:

FIG. 1 a schematic illustration of a base station according to an embodiment;

FIG. 2 a more detailed view of a base station, including a multi-band antenna being wired with a radio unit according to an embodiment;

FIG. 3 a schematic detailed view of a phase shifter according to an embodiment of the present invention, and

FIG. 4 a schematic flow chart of the inventive method according to an embodiment.

### DETAILED DESCRIPTION

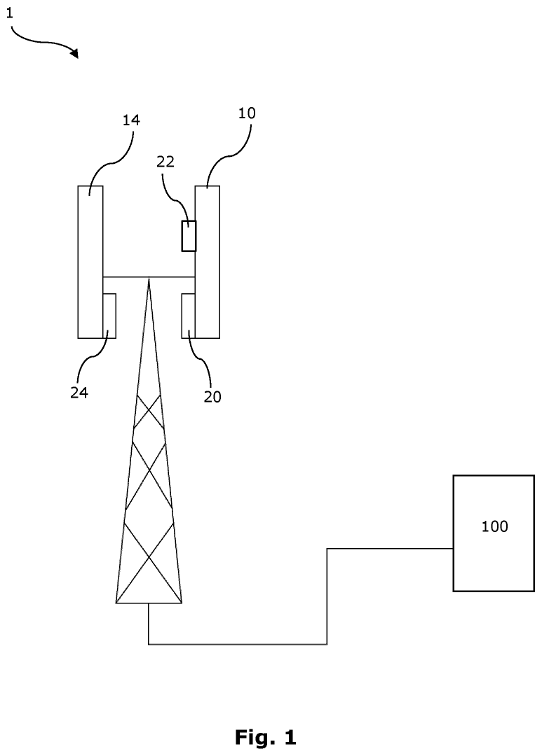

FIG. 1 shows a schematic illustration of a base station 1 according to an embodiment. The base station 1 incudes control unit 100, such as a based band unit (BBU), which is in communication with radio units 20, 22, 24. Those radio units 20, 22, 24 may be remote radio units, which may be remotely controlled by the control unit. The radio units 20, 22 are assigned to a first multi band antenna 10 of the base station 1 and the radio unit 24 is assigned to a second multi band antenna 14 of the base station 1. Each one of the multi-band antennas 10, 14 may include a remote control unit for enabling e.g. controlling phase shifters of the respective multi-band antenna by means of the control unit 100. Hence, remote electrical tilt (RET) can be provided.

The control unit 100 is connected via respective data lines to the radio units 20, 22, 24. Each one of the radio units 20, 22, 24 powers a respective base station antenna (i.e. multi-band antennas 10, 14), or at least parts thereof. The radio units 20, 22, 24 are operatively coupled to the multi band antennas 10, 14 via jumper cables (not shown here).

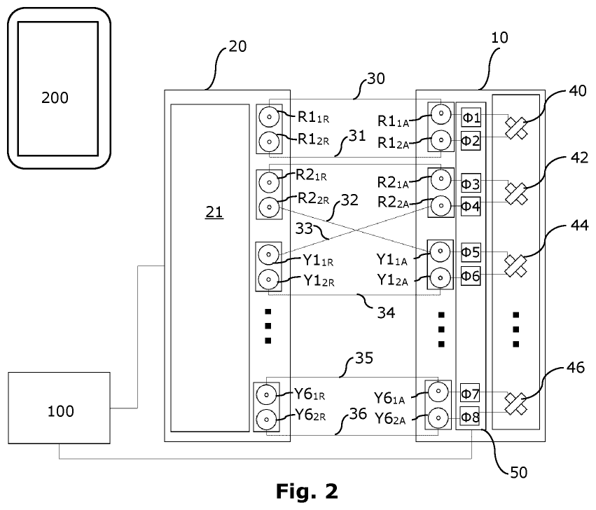

FIG. 2 is a more detailed view of a base station according to an embodiment, including a multi-band antenna 10 being wired (mated) with a radio unit 20. The radio unit 20 includes a transceiver 21. The wiring is done via jumper cables 30, 31, 32, 33, 34, 35, 36, being mated to respective antenna ports and ports of the radio unit.

The multi-band antenna 10 includes multiple antenna elements 40, 42, 44, 46. Those antenna elements 40, 42, 44, 46 are dual polarized radiators, each assigned to a respective band. For example, antenna element 40 is assigned to band R1, antenna element 42 is assigned to band R2, antenna element 44 is assigned to band Y1 and antenna element 46 is assigned to band Y6. Further antenna elements and bands may be provided. Each one of the antenna elements 40, 42, 44, 46 can be connected via two antenna ports R1_{1A}, R1_{2A}, R2_{1A}, R2_{2A}, Y1_{2A}, Y2_{2A}, Y6_{1A}, Y6_{2A} to a respective one of the R1_{1R}, R1_{2R}, R2_{1R}, R2_{2R}, Y1_{2R}, Y2_{2R}, Y6_{1R}, Y6_{2R} of the radio unit 20. This may be done via jumper cables 30, 31, 32, 33, 34, 35, 36. If correctly mated antenna port R1_{1A} would be mated with port R1_{1R} of the radio unit, antenna port R1_{2A} would be mated with port R1_{2R} of the radio unit, antenna port R2_{1A} would be mated with port R2_{1R} of the radio unit, antenna port R2_{2A} would be mated with port R2_{2R} of the radio unit, and so on.

Further, phase shifters φ1, . . . φ8 are assigned to respective antenna ports R1_{1A}, . . . Y6_{2A} of the multiband antenna 10. Hence, in case the mating would be correct, changing a phase shift of a phase shifter φ1 (which is assigned to antenna port R1_{1A}) would result in a change in the VSWR at port R1_{1R} of the radio unit. In other words, R1_{1R} is the intended port for antenna port R1_{1A}. The same applies, mutatis mutandis for the remaining ports. The change in phase shift may be controlled by means of the remote control unit 50 that is adapted to control the phase shifters φ1, . . . φ8.

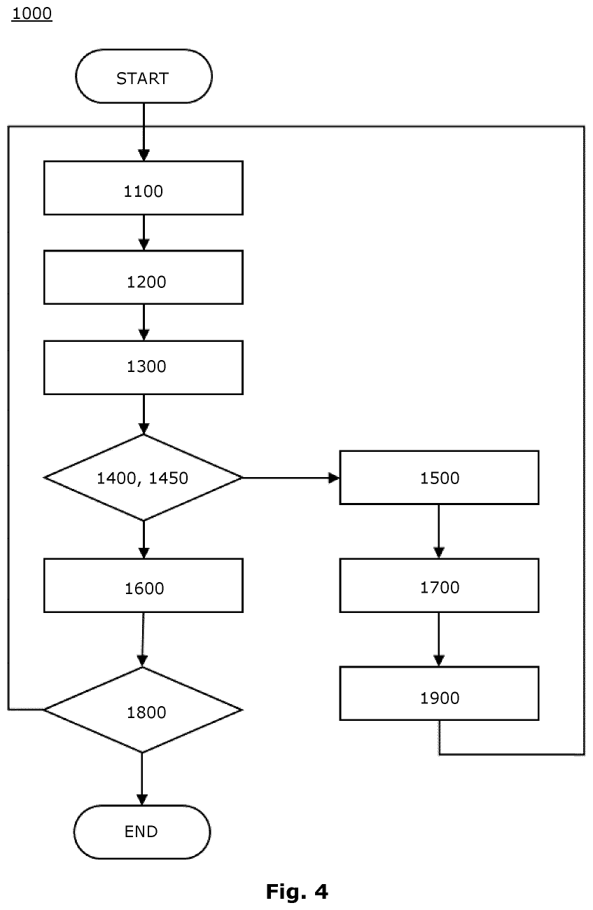

In FIG. 2, however, the mating is erroneous, as jumper cables 32 and 33 are incorrectly mated. Particularly, port R2_{2R} is erroneously mated with port Y1_{1A} and not with the intended port R2_{2A}. Likewise port Y1_{1R} is erroneously mated with port R2_{2A} and not with the intended port Y1_{1A}. This mating failure may be detected with the inventive method 1000, which is described in detail with regard to FIG. 4.

Particularly, the method may be performed by the control unit 100, by the radio unit 20 and/or by the analyzing device 200, which may be a smart phone or tablet computer.

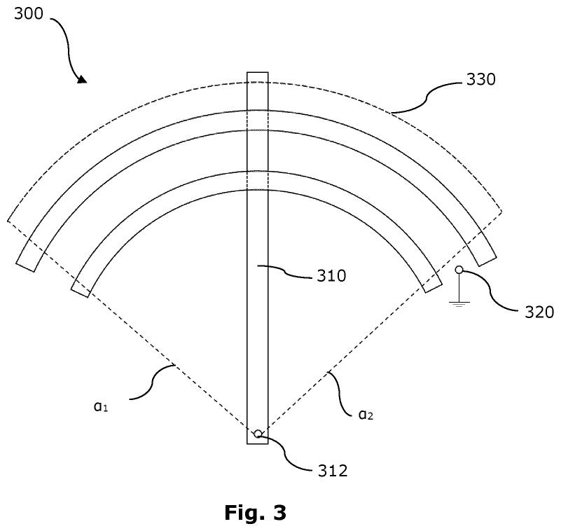

FIG. 3 is a schematic detailed view of a phase shifter 300 according to an embodiment of the present invention. The phase shifter 300 is adapted to be used in a method 1000, which is described in detail with regard to FIG. 4.

Said phase shifter 300 may be coupled with an antenna port of a multi-band antenna. Further the phase shifter 300 comprises a phase shift changing element 310 and a ground coupling element 320. In the embodiment depicted in FIG. 3, the phase shift changing element 310 is a wiper, that is arranged moveable and can be moved from a first position α₁ (corresponding to a minimum phase shift value) to a second position α₂ (corresponding to a maximum phase shift value). The area between the first position α₁ and the second position α₂ defines a phase shift changing area 330. The phase shift changing element 310 can be rotated within this phase shift changing area 330 to change a phase shift of the phase shifter 300.

The ground coupling element 320 is electrically connected to ground and is arranged outside the phase shift changing area 330. However, the phase shift changing element 310 is configured to be moved out of the phase shift changing area 330. When it comes into contact with the ground coupling element 310, wherein the contact can be capacitively or galvanically, i.e. DC coupled, the VSWR of the phase shifter 300 will considerably increase, which can be detected to check the cable mating of the differently polarized radiators.

FIG. 4 is a schematic flow chart of the inventive method 1000 for checking the cable mating between a radio unit and a multi-band antenna. The method 1000 comprises the steps of:
monitoring 1100 a voltage standing wave ratio, VSWR, of the radio unit,
changing 1200 a phase shift of a phase shifter φ1, . . . φ8 being assigned to an antenna port R1_{1A}, . . . Y6_{2A} of the multi-band antenna 10, which optionally includes commanding a phase shift changing element of a phase shifter to move beyond a position α₁, α₂ corresponding to a minimum phase shift value or a maximum phase shift value so as to electrically couple with a ground coupling element of the phase shifter,
determining 1300 a port R1_{1R}, . . . Y6_{2R} of the radio unit 20, where a change in the VSWR of the radio unit occurred due to the changing of the phase shift, and checking 1400, whether the determined port R1_{1R}, . . . Y6_{2R} of the radio unit 20 corresponds to the antenna port R1_{1A}, . . . Y6_{2A} of the multi-band antenna 10, where the phase shift was changed,
additionally, and/or alternatively to step 1400, checking 1450 whether a change in the VSWR of the radio unit occurred at an intended port, the intended port being assigned to the antenna port where the phase shift change was applied,
outputting 1500 an OK result of the checking or outputting 1600 an NOK result of the checking,
optionally determining and/or outputting 1700, which of the ports R1_{1R}, . . . Y6_{2R} of the radio unit and the antenna ports R1_{1A}, . . . Y6_{2A} are interchanged, this may include outputting a list of the actual mating of the ports,
optionally determining 1800, whether all ports whose mating is to be checked are correctly mated, and further optionally enabling mobile communication via the multi-band antenna only after having proved that all ports whose mating is to be checked are correctly mated, and
further optionally correcting 1900 the mating of interchanged ports based on the outputted result of the checking.

Some of the steps may be repeated or may be performed in a different order, without deviating from the scope of the invention.

Some of the embodiments contemplated herein are described more fully with reference to the accompanying figures. Other embodiments, however, are contained within the scope of the subject matter disclosed herein. The disclosed subject matter should not be construed as limited to only the embodiments set forth herein; rather, these embodiments are provided by way of example to convey the scope of the subject matter to those skilled in the art.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

List of reference signs

| | |
|---|---|
| 1 | base station |
| 10 | multi band antenna (e.g. a base station antenna) |
| 14 | multi band antenna (e.g. a base station antenna) |
| 20 | radio Unit (e.g. a RRU) |
| 21 | transceiver |
| 22 | radio Unit (e.g. a RRU) |
| 24 | radio Unit (e.g. a RRU) |
| 30 | jumper cable |
| 31 | jumper cable |
| 32 | jumper cable |
| 33 | jumper cable |
| 34 | jumper cable |
| 35 | jumper cable |
| 36 | jumper cable |
| 40 | antenna element |
| 42 | antenna element |
| 44 | antenna element |
| 46 | antenna element |
| 50 | remote control unit |
| 100 | control unit, e.g. a base band unit (BBU) |
| 200 | analyzing device |
| 300 | phase shifter |
| 310 | phase shift changing element (e.g. a wiper) |
| 312 | rotational axis |
| 320 | ground coupling element |
| 330 | phase shift changing area |
| α₁ | first position (minimum tilt) |
| α₂ | second position (maximum tilt) |
| R1_{1A} | antenna port |
| R1_{2A} | antenna port |
| R2_{1A} | antenna port |
| R2_{2A} | antenna port |
| Y1_{1A} | antenna port |
| Y1_{2A} | antenna port |
| Y6_{1A} | antenna port |
| Y6_{2A} | antenna port |
| R1_{1R} | port of radio unit |
| R1_{2R} | port of radio unit |
| R2_{1R} | port of radio unit |
| R2_{2R} | port of radio unit |
| Y1_{1R} | port of radio unit |
| Y1_{2R} | port of radio unit |
| Y6_{1R} | port of radio unit |
| Y6_{2R} | port of radio unit |
| φ1 | phase shifter |
| φ2 | phase shifter |
| φ3 | phase shifter |
| φ4 | phase shifter |
| φ5 | phase shifter |
| φ6 | phase shifter |
| φ7 | phase shifter |
| φ8 | phase shifter |
| 1000 | Method |
| 1100 | monitoring VSWR |
| 1200 | changing phase shift |
| 1300 | determining port |
| 1400 | checking port assignment |
| 1450 | checking intended port |
| 1500 | outputting result NOK |
| 1600 | outputting result OK |
| 1700 | determining and/or outputting interchanged ports |
| 1800 | determining whether all ports a OK |
| 1900 | change mating |

1. A method for checking a cable mating between a radio unit and a multi-band antenna, the method comprising:
monitoring a voltage standing wave ratio, VSWR, of the radio unit;
changing a phase shift of a phase shifter being assigned to an antenna port of the multi-band antenna;
determining a port of the radio unit, where a change in the VSWR of the radio unit occurred due to the changing of the phase shift and
checking whether the determined port of the radio unit corresponds to the antenna port of the multi-band antenna, where the phase shift was changed; and/or
checking whether a change in the VSWR of the radio unit occurred at an intended port, the intended port being assigned to the antenna port where the phase shift change was applied; and
outputting the result of the checking.

2. The method according to claim 1, further comprising determining and/or outputting, which of the ports of the radio unit and the antenna ports are interchanged.

3. The method according to claim 1, further comprising:
determining, whether all ports whose mating is to be checked are correctly mated, and optionally
enabling mobile communication via the multi-band antenna only after having proved that all ports whose mating is to be checked are correctly mated.

4. The method according to claim 1, wherein the step of changing a phase shift includes sending a phase shift changing command to a remote electrical tilt, RET, unit.

5. The method according to claim 1, wherein the step of monitoring a voltage standing wave ratio, VSWR, of the radio unit includes receiving a VSWR monitoring signal.

6. The method according to claim 4, wherein the phase shift changing command and/or the VSWR monitoring signal is transmitted via AISG signaling.

7. The method according to claim 1, wherein a transmission power of the radio unit and/or a transmission power of the port of the radio unit, where a change in the VSWR of the radio unit occurred due to the changing of the phase shift is reduced or shut off, if the VSWR exceeds a predefined VSWR-threshold.

8. The method according to claim 1, wherein the step of changing a phase shift of a phase shifter includes changing the phase shift from a minimum value to a maximum value and/or vice versa.

9. The method according to claim 1, wherein the step of changing a phase shift of a phase shifter includes commanding a phase shift changing element of a phase shifter to move beyond a position corresponding to a minimum phase shift value or a maximum phase shift value so as to electrically couple with a ground coupling element of the phase shifter.

10. The method according to claim 1, further comprising correcting the mating of interchanged ports based on the outputted result of the checking.

11. A computer program product comprising a non-transitory computer readable medium storing a computer program comprising instructions, which, when executed by processing circuitry, cause the processing circuitry to perform a method according to claim 1.

12. A phase shifter, the phase shifter being adapted to be used in a method according to claim 1, and to be coupled with an antenna port of a multi-band antenna, the phase shifter comprising
a phase shift changing element being arranged moveable from a first position corresponding to a minimum phase shift value to a second position corresponding to a maximum phase shift value, wherein an area between the first position and the second position defines a phase shift changing area, wherein the phase shift changing element is moveable within this phase shift changing area to change a phase shift of the phase shifter; and
a ground coupling element, the ground coupling element being electrically connected to ground and arranged outside the phase shift changing area, wherein
the phase shift changing element is configured to be moved out of the phase shift changing area to electrically contact the ground coupling element.

13. An analyzing device, the analyzing device being adapted to
communicate with at least one radio unit and a multi-band antenna, wherein
the analyzing device is further adapted to perform a method according to claim 1.

14. The analyzing device according to claim 13, wherein the analyzing device is a portable device.

15. A radio unit, being adapted to communicate with a multi-band antenna, wherein
the radio unit is further adapted to perform a method according to claim 1.

16. A base station for mobile communication, the base station including
at least one multi-band antenna, and
at least one radio unit being assigned to said multi-band antenna; the base station further including
a control unit, wherein the control unit is adapted to communicate with the at least one radio unit and the at least one multi-band antenna, wherein
the control unit is further adapted to perform a method according to claim 1.
